(19) United States
(12) Patent Application Publication
(10) Pub. No.: US 2026/0076245 A1
(43) Pub. Date: Mar. 12, 2026

(54) METAL BUMP CONTAINING STRUCTURE

(71) Applicant: International Business Machines Corporation, Armonk, NY (US)

(72) Inventors: Toyohiro Aoki, Yokohama-shi (JP); Takahito Watanabe, Yokohama-shi (JP); KOKI NAKAMURA, Kawasaki (JP)

(21) Appl. No.: 18/828,525

(22) Filed: Sep. 9, 2024

(51) Int. Cl. H01L 23/00

(52) U.S. Cl. CPC H10W 72/20; H10W 72/012; H10W 72/01235; H10W 72/07254; H10W 72/221; H10W 72/223; H10W 72/234; H10W 72/241; H10W 72/252; H10W 72/255

(57) ABSTRACT

A metal bump containing structure is provided which has a substantially flat top surface and enhanced coplanarity with other like metal bump containing structures. The metal bump containing structures include a metal bump having a curved top surface, and a first metal liner located along an outermost sidewall and present at least partially on the curved top surface of the metal bump.

### BACKGROUND

The present application relates to semiconductor technology, and more particularly to a metal bump containing structure with a substantially flat top surface and enhanced coplanarity, methods of forming such a structure, and plate fixtures that can be used in the methods of the present application.

Fine pitch bonding with copper bumps is a critical aspect of advanced semiconductor packaging, where the goal is to create high-density interconnects that can handle an increasing volume of data being processed. This technology is essential for enabling faster data movement and ensuring signal integrity between components in integrated circuit (IC) packages.

In the context of fine pitch bonding, copper microbumps are often used due to their smaller size compared to traditional solder balls, allowing for more I/Os in packages. For instance, in advanced packages, microbumps with a 40 μm pitch are common, which translates to bump sizes of 20 μm to 25 μm with 15 μm spacing between adjacent bumps on the die.

As the industry moves beyond 40 μm pitches, there are options such as continuing to use existing bump technologies down to 10 μm pitches or adopting newer technologies like metal-to-metal bonding. Metal-to-metal bonding does not rely on bumps in the package; instead, it uses tiny copper-to-copper interconnects, enabling finer-pitch packages with more I/Os than traditional packages.

### SUMMARY

A metal bump containing structure is provided which has a substantially flat top surface and enhanced coplanarity with other like metal bump containing structures. The metal bump containing structures include a metal bump having a curved top surface, and a first metal liner located along an outermost sidewall and present at least partially on the curved top surface of the metal bump.

In one aspect of the present application, a structure is provided that includes a metal bump containing structure having a substantially flat top surface and located on top of a substrate, the metal bump containing structure includes a metal bump having a curved top surface, and a first metal liner located along an outermost sidewall and present at least partially on the curved top surface of the metal bump.

In another aspect of the present application, a method is provided that includes forming a metal seed layer on a substrate, plating a metal bump on the metal seed layer, the metal bump having a curved top surface, and plating a first metal liner on an outermost sidewall and at least partially on the curved top surface of the metal bump in which the plating of the first metal liner is performed in a plating solution and in the presence of a plate fixture that is in contact with, or close proximity to, the metal bump.

### BRIEF DESCRIPTION OF THE DRAWINGS

FIG. 1A is a cross sectional view of a first exemplary structure in accordance with an embodiment of the present application.

FIG. 1B is a cross sectional view of a second exemplary structure in accordance with an embodiment of the present application.

FIG. 2 is a cross sectional view of a third exemplary structure in accordance with an embodiment of the present application.

FIG. 3 is a cross sectional view of a fourth exemplary structure in accordance with an embodiment of the present application.

FIG. 4A is a cross sectional view of an initial structure that can be employed in the present application, the initial structure including a substrate, an adhesion layer located on a surface of the substrate, and a metal seed layer located on the adhesion layer.

FIG. 4B is a cross sectional view of the initial structure shown in FIG. 4A after forming a patterned bilayer photoresist on the metal seed layer.

FIG. 4C is a cross sectional view of the structure shown in FIG. 4B after forming, by electroplating, metal bumps on physically exposed surfaces of the metal seed layer.

FIG. 4D is a cross sectional view of the structure shown in FIG. 4C after removing a second photoresist layer of the patterned bilayer photoresist.

FIG. 4E is a cross sectional view of the structure shown in FIG. 4D during an initial stage of forming a first metal liner in which a plating solution is provided and thereafter a plate fixture is brought into contact with, or close proximity to, each of the metal bumps.

FIG. 4F is a cross sectional view of the structure shown in FIG. 4E during a step of refreshing the plating solution in which the plate fixture is removed from being in contact with, or close proximity to, each of the metal bumps; the plate fixture is then pushed back so as to be in contact with, or close proximity to, each of the metal bumps.

FIG. 4G is a cross sectional view of the structure shown in FIG. 4F after plating a first metal liner on physically exposed surfaces of each metal bump.

FIG. 4H is a cross sectional view of the structure shown in FIG. 4G after removing the plate fixture and depositing a second metal liner on the first metal liner.

FIG. 4I is a cross sectional view of the structure shown in FIG. 4G after removing a first photoresist layer of the patterned bilayer photoresist, and removing physically exposed portions of the metal seed layer and the adhesion layer.

FIG. 4J is a cross sectional view of an exemplary structure in which the second metal liner is not formed.

FIG. 5A is a cross sectional of an initial structure that can be employed in the present application, the initial structure including a substrate and metal bumps.

FIG. 5B is a cross sectional view of the structure shown in FIG. 5A during an initial stage of forming a first metal liner in which a plating solution is provided and thereafter a plate fixture is brought into contact with, or close proximity to, each of the metal bumps.

FIG. 5C is a cross sectional view of the structure shown in FIG. 5B during a step of refreshing the plating solution in which the plate fixture is removed from being in contact with, or close proximity to, each of the metal bumps; the plate fixture is then pushed back so as to be in contact with, or close proximity to, each of the metal bumps.

FIG. 5D is a cross sectional view of the structure shown in FIG. 5C after plating a first metal liner on physically exposed surfaces of each metal bump.

FIG. 5E is a cross sectional view of the structure shown in FIG. 5D after removing the plate fixture and depositing a second metal liner on the first metal liner.

FIG. 6A is a top down view of a plate fixture that can be employed in accordance with an embodiment of the present application.

FIG. 6B is a cross sectional view of an application of the plate fixture shown in FIG. 6A during an initial stage of plating the first metal liner.

FIG. 7A is a cross sectional view of a plate fixture including at least one cavity that can be employed in accordance with an embodiment of the present application.

FIG. 7B is a cross sectional view of another plate fixture including at least one cavity that can be employed in accordance with an embodiment of the present application.

FIG. 7C is a cross sectional view of yet another plate fixture including at least one cavity that can be employed in accordance with an embodiment of the present application.

FIG. 8 is a top down view of a plate fixture including slits and a sealing edge that can be employed in accordance with an embodiment of the present application.

FIG. 9A is a cross sectional view of a plate fixture as shown in FIG. 8 for application with a plurality of substrate containing metal bumps.

FIG. 9B is a cross sectional view of a plate fixture as shown in FIG. 8 for application with a substrate containing metal bumps.

FIG. 9C is a cross sectional view of a plate fixture as shown in FIG. 8 for application with a substrate containing metal bumps illustrating inlet slits and outlet slits.

FIG. 10A is a cross sectional view of an initial stage of a bonding process in accordance with an embodiment of the present application.

FIG. 10B is a cross sectional view of a final stage of a bonding process in accordance with an embodiment of the present application.

FIG. 11A is a cross sectional view of an initial stage of a bonding process in accordance with an embodiment of the present application.

FIG. 11B is a cross sectional view of a final stage of a bonding process in accordance with an embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Fine pitch bonding becomes challenging when coplanarity of metal bumps is large relative to the pitch. Metal bumps with improved coplanarity are required for finer pitch devices. Also, a metal bump having a flat surface will be helpful to obtain good joints by increasing contact area with lower bonding force. For fine pitch applications, metal-to-metal (e.g., copper-to-copper) bonding is superior to solder bonding in terms of bump short or electrical property. Coplanarity and flat surfaces of metal bumps are necessary for fine pitch metal-to-metal bonding with lower bonding force.

Copper electroplating is optimized for each applications such as, for example, bump formation, Cu wiring formation, and through-silicon-via (TSV) filling. Despite this, it is difficult to form copper bumps having a flat top surface and good coplanarity by optimizing the plating solution. Enhanced coplanarity is required for metal-to-metal bonding (i.e., copper-to-copper) to obtain strong bonds for finer pitch applications.

Chemical mechanical planarization (CMP) is one solution for forming flat bump surfaces and good bump coplanarity. CMP for copper direct bonding applications, where the Cu bumps are not surrounded by an insulation layer such as, for example, a dielectric oxide (e.g., SiO₂) or a dielectric nitride (e.g., silicon nitride), is more challenging. For example and for Cu/SiO₂ layers, CMP causes dishing and erosion due to the etching/polishing rate difference and pattern density effect. For Cu/organic layers, there are some level of bump height variation after CMP which is undesirable in some applications.

Metal bump containing structures are provided in the present application which have a substantially flat top surface and enhanced coplanarity (defined by a substantially uniform height). Throughout the present application, the term “substantially flat top surface” denotes that the surface roughness, Rz, of the top surface is less than 0.5 microns, more particularly less than 0.2 microns, and even more particularly less than 0.1 microns. Throughout the present application, the term “enhanced coplanarity” denotes that the height variation between metal bump containing structures is less than 5.0 microns, more particularly less than 1.0 microns, and even more particularly less than 0.5 microns.

The metal bump containing structures are provided by first forming (via electroplating or electroless plating) a metal bump on a substrate (e.g., a wafer, a die, or a chiplet), and then plating a first metal liner 26 to surround the metal bump 22 using a plate fixture. The plate fixture is a movable structure which can be made to contact, or be in close proximity to, each of the metal bumps 22 during the plating of the first metal liner 26. The presence of the plate fixture during the plating of the first metal liner 26 provides metal bump containing structures which have a substantially flat top surface and enhanced coplanarity. One or more additional metal liners can be plating on the first metal liner. The metal bump containing structures can be used for metal-to-metal joining or metal-to-solder joining. These and other aspects of the present application will now be described in greater detail.

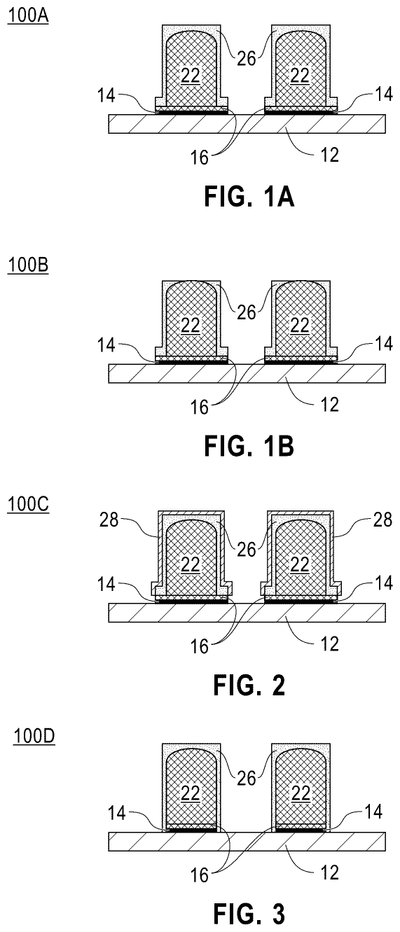

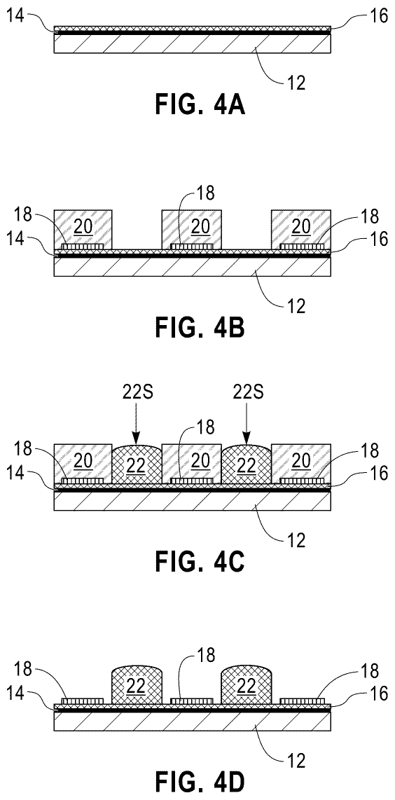

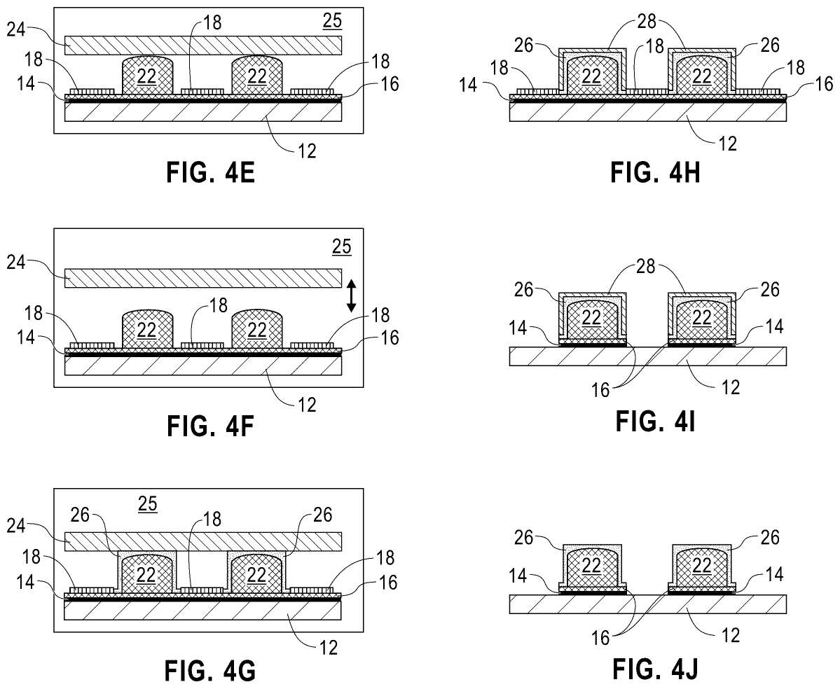

Referring first to FIGS. 1A, 1B, 2 and 3, there are illustrated exemplary structures in accordance with various embodiments of the present application. Notably, FIG. 1A illustrates a first exemplary structure 100A in accordance with an embodiment of the present application. The first exemplary structure 100A illustrated in FIG. 1 includes metal bumps 22 (two of which are shown by way of one example in FIG. 1A) located on substrate 12. Each of the metal bumps 22 has a curved top surface; in FIG. 4C the curved top surface 22S is specifically shown. That is, each metal bump 22 has a rounded top surface. In embodiments, the metal bumps 22 are disposed on metal seed layer 16, and the metal seed layer 16 is located on adhesion layer 14. In some embodiments, the adhesion layer 14 is omitted from the first exemplary structure shown in FIG. 1A. The first exemplary structure 100A also includes first metal liner 26 located on an outermost sidewall of each of the metal bumps 22 and entirely along the curved top surface of each of the metal bumps 22. In this embodiment, the first metal liner 26 is a fully encapsulating metal liner. Each metal bump 22-first metal liner 26 combination provides a metal bump containing structure which has a substantially flat top surface and enhanced coplanarity. In embodiments, the adhesion layer 14 and the metal seed layer 16 are located between the metal bump containing structure and the substrate 12. It is noted that the metal seed layer 16 forms a base of the metal bump 22, and in this embodiment the base (i.e., the metal seed layer 16) of each metal bump 22 has a width that is larger than a width (i.e., diameter) of the metal bump 22. The larger base (i.e., the metal seed layer 16) as compared to the dimension of the metal bumps 22 is a result of the metal bumps 22 being formed by an electroplating process as will be illustrated in FIGS. 4A-4J. The larger base has a rougher surface than that of the top surface of the metal bump containing structure.

Notably, FIG. 1B illustrates a second exemplary structure 100B in accordance with an embodiment of the present application. The second exemplary structure 100B illustrated in FIG. 1B is similar to the exemplary first structure 100A shown in FIG. 1A except that in the second exemplary structure 100B illustrated in FIG. 1B, the first metal liner 26 is present on outermost sidewall of each of the metal bumps 22 and partially on the top surface of each of the metal bumps 22. In such an embodiment, the first metal liner 26 can be referred to as a partially encapsulating liner. Each metal bump 22-first metal liner 26 combination provides a metal bump containing structure which has a substantially flat top surface and enhanced coplanarity. It is noted that the metal seed layer 16 forms a base of the metal bump 22, and in this embodiment the base (i.e., the metal seed layer 16) of each metal bump 22 has a width that is larger than a width (i.e., diameter) of the metal bump 22. The larger base (i.e., the metal seed layer 16) as compared to the dimension of the metal bumps 22 is a result of the metal bumps 22 being formed by an electroplating process as will be illustrated in FIGS. 4A-4J. The larger base has a rougher surface than that of the top surface of the metal bump containing structure.

Referring now to FIG. 2, there is illustrated a third exemplary structure 100C in accordance with an embodiment of the present application. The third exemplary structure 100C illustrated in FIG. 2 is similar to the exemplary first structure 100A shown in FIG. 1A except that in the third exemplary structure illustrated in FIG. 2, a second metal liner 28 is present on the first metal liner 26. Each metal bump 22-first metal liner 26 combination provides a metal bump containing structure which has a substantially flat top surface and enhanced coplanarity. The presence of the second metal liner 28 further improves the flatness and coplanarity of each metal bump containing structure. It is noted that the metal seed layer 16 forms a base of the metal bump 22, and in this embodiment the base (i.e., the metal seed layer 16) of each metal bump 22 has a width that is larger than a width (i.e., diameter) of the metal bump 22. The larger base (i.e., the metal seed layer 16) as compared to the dimension of the metal bumps 22 is a result of the metal bumps 22 being formed by an electroplating process as will be illustrated in FIGS. 4A-4J. The larger base has a rougher surface than that of the top surface of the metal bump containing structure. It is noted that the second metal liner 28 illustrated in this embodiment can be implemented in the second exemplary structure 100B to further enhance the flatness and coplanarity of each metal bump containing structure shown in FIG. 1B.

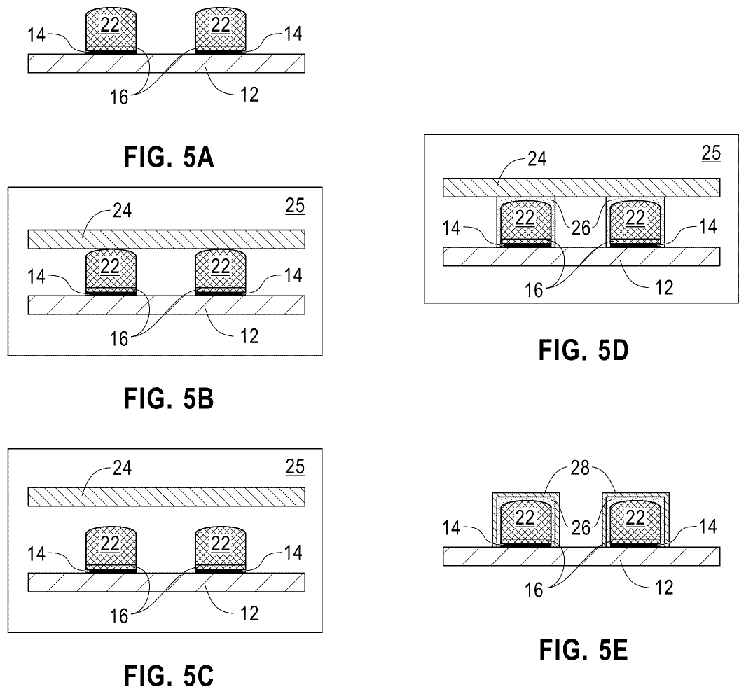

Referring now to FIG. 3, there is illustrated a fourth exemplary structure 100D in accordance with an embodiment of the present application. The fourth exemplary structure 100D illustrated in FIG. 3 includes metal bumps 22 (two of which are shown by way of one example in FIG. 3) located on substrate 12. Each of the metal bumps 22 has a curved top surface. That is, each metal bump 22 has a rounded top surface. In embodiments, the metal bumps 22 are disposed on metal seed layer 16, and the metal seed layer 16 is located on adhesion layer 14. In the present application, the adhesion layer 14 and the metal seed layer 16 are located between the metal bump containing structure and the substrate 12. In some embodiments, the adhesion layer 14 is omitted from the first exemplary structure shown in FIG. 3. The fourth exemplary structure 100D also includes first metal liner 26 located on an outermost sidewall of each of the metal bumps 22 and entirely along the curved top surface of each of the metal bumps 22. In this embodiment, the first metal liner 26 is a fully encapsulating metal liner. Each metal bump 22-first metal liner 26 combination provides a metal bump containing structure which has a substantially flat top surface and enhanced coplanarity. It is noted that the metal seed layer 16 forms a base of the metal bump 22, and in this embodiment the base (i.e., the metal seed layer 16) of each metal bump 22 has a same width as a width (i.e., diameter) of the metal bump 22. In this embodiment, the metal bumps 22 can be formed by an electroless plating process as will be illustrated in FIGS. 5A-5E.

Although not shown in FIG. 3, the fully encapsulating first metal liner illustrated in FIG. 3 can be replaced with a partially encapsulating first metal liner as is shown in FIG. 1B. Also, and although not shown in FIG. 3, a second metal liner can be formed on the first metal liner 26 (fully encapsulating or partially encapsulating first metal liner).

In each of FIGS. 1A, 1B, 2 and 3, there is illustrated a structure in accordance with the present. The structures illustrated in FIGS. 1A, 1B, 2 and 3 include a metal bump containing structure having a substantially flat top surface and located on top of substrate 12. The metal bump containing structure includes metal bump 22 having a curved top surface 22S (as evidenced in FIG. 4C), and first metal liner 26 is located along an outermost sidewall and present at least partially on the curved top surface 22S of the metal bump 22. In each of FIGS. 1A, 1B, 2 and 3, two spaced apart metal bump containing structures in accordance with the present application are present on substrate 12, and the substantially flat top surfaces of two spaced apart metal bump containing structures are coplanar with each other.

The various elements illustrated in FIGS. 1A, 1B, 2 and 3 will be described in greater detail with respect to the electroplating process illustrated in FIGS. 4A-4I.

Referring now to FIGS. 4A-4I, there are illustrated a process flow (i.e., an electroplating process flow) that can be employed in the present application in providing an exemplary structure in accordance with the present application. Electroplating, also known as electrochemical deposition or electrodeposition, is a process for producing a metal coating on a solid substrate through the reduction of cations of that metal by means of a direct electric current. The part to be coated acts as the cathode (negative electrode) of an electrolytic cell; the electrolyte is a solution of a salt of the metal to be coated, and the anode (positive electrode) is usually either a block of that metal, or of some inert conductive material. The current is provided by an external power supply. Any conventional electroplating apparatus can be used in the present application.

The electroplating process flow begins by providing the initial structure illustrated in FIG. 4A. The initial structure illustrated in FIG. 4A includes substrate 12, adhesion layer 14 located on a surface of the substrate 12, and metal seed layer 16 located on the adhesion layer 14. The adhesion layer 14 is optional and is not needed when good adhesion between the metal seed layer 16 and the substrate 12 can be obtained.

The substrate 12 can be a wafer, or it can be a die (or chip), a die stack (or chip stack), a chiplet or a stack of chiplets. The substrate 12 can include at least a semiconductor device layer that is composed of a semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The substrate 12 can include one or more semiconductor devices such as, for examples, transistors, capacitors and/or resistors that are formed upon the semiconductor device layer utilizing device processing techniques that are well known in the art. The substrate 12 can also include a middle-of-the-line (MOL) level and a frontside back-end-of the line (BEOL) structure that are formed on a frontside of the semiconductor device layer, and, in some cases, a backside BEOL structure can be formed on a backside of the semiconductor device layer. Embodiments are contemplated in which the semiconductor device layer is removed from the substrate 12 after forming the MOL level and the frontside BEOL structure, and prior to forming the backside BEOL structure.

A MOL level includes one or more interlayer dielectric (ILD) layers in which metal contact structures are present therein. A frontside BEOL structure includes one or more ILD layers in which frontside metal wiring is present therein, and backside BEOL structure includes one or more ILD layers in which backside metal wiring is present therein. The MOL level, frontside BEOL structure and backside BEOL structure can be formed utilizing techniques well known those skilled in the art. Each of the metal contact structures, the frontside wiring and the backside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. Each of the ILD layers can be composed of ILD material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. All dielectric constants measured herein are measured in a vacuum unless otherwise is stated.

In the illustrated embodiment of the present application, the adhesion layer 14 is formed on an uppermost surface of the substrate 12, and then the metal seed layer 16 is formed on the adhesion layer 14. In some embodiments, the adhesion layer 14 can be omitted. In such embodiments, the metal seed layer 16 is formed on an uppermost surface of substrate 12. With respect to the embodiment illustrated in FIG. 4A, the adhesion layer 14 is composed of an adhesion metal-containing material such as, for example, Ti, Ta, TiN, TaN, Cr or CrCu. The adhesion layer 14 can be a single layer, or it can be a multilayered stack of at least two different adhesion metal-containing materials (e.g., Ti/TiN). The metal seed layer 16 is composed of a first metal which is selected to facilitate the electroplating of a subsequent metal bump 22. Illustrative first metals that can be used in providing the metal seed layer 16 include, but are not limited to, Ni, Cu or Ag. In one example, the adhesion layer 14 is composed of Ti, and the metal seed layer 16 is composed of Cu. Each of the adhesion layer 14 and the metal seed layer 16 can be formed by a deposition process, including, but not limited to, chemical vapor deposition (CVD), plasma enhanced chemical vapor deposition (PECVD), physical vapor deposition (PVD), sputtering or atomic layer deposition (ALD). The metal seed layer 16 can be formed utilizing a same deposition process as, or a different deposition process than, that used in forming the adhesion layer 14.

Referring now to FIG. 4B, there is illustrated the initial structure shown in FIG. 4A after forming a patterned bilayer photoresist on the metal seed layer 16. The patterned bilayer photoresist is composed of a first photoresist layer 18 and a second photoresist layer 20. The patterned bilayer photoresist can be formed by photolithography which includes deposition of a first resist (which provides the first photoresist layer 18) and a second resist (which provides the second photoresist layer 20), followed exposing the first and second resists. The patterned bilayer photoresist protects portions of the underlying metal seed layer 16, while leaving at least one other portion of the underlying metal seed 16 physically exposed. Each physically exposed portion of the underlying metal seed layer 16 is located between a gap in the patterned bilayer photoresist. As mentioned above, the first photoresist layer 18 is composed of a first resist, while the second photoresist layer 20 is composed of a second resist; the second resist is compositionally different from the first resist. This aspect also for a different removal rate between the first photoresist layer 18 and the second photoresist layer 20 such that second photoresist layer 20 can be subsequently removed selective to the first photoresist layer 18. In some embodiments of the present application, the first photoresist layer 18 can be composed of a negative resist and the second photoresist layer 20 can be composed of a positive resist. Commercially available resists can be employed as will be familiar to a skilled artisan.

Referring now to FIG. 4C, there is illustrated the structure shown in FIG. 4B after forming, by electroplating, metal bumps 22 on physically exposed surfaces of the metal seed layer 16. Although the present application describes and illustrates forming a plurality of metal bumps 22, the present application works when a single metal bump 22 is formed. Each metal bump 22 can also be referred to as a metal pillar. Each metal bump 22 is formed between one of the gaps in the patterned bilayer photoresist. Each metal bump 22 is composed of a second metal. The second metal is typically, but not necessarily always, a compositionally same metal as the first metal that provides the metal seed layer 16. Illustrative examples of second metals that can be used in providing the metal bumps 22 include, but are not limited to, Cu, Ni, Sn, In Bi or multi-element alloys mainly including one of the aforementioned exemplary second metals. In one example, the metal seed layer 16 is composed of Cu and the metal bumps 22 are also composed of Cu.

In embodiments in which the first metal that provides the metal seed layer 16 is a compositionally same metal as the second metal that provides the metal bumps 22, no material interface would be present between the metal seed layer 16 and the metal bumps 22. In embodiments in which the first metal that provides the metal seed layer 16 is a compositionally different metal than the second metal that provides the metal bumps 22, a material interface would be present between the metal seed layer 16 and the metal bumps 22. In the present application, a solid line is drawn between the metal seed layer 16 and the overlying metal bump 22 to represent both embodiments.

Each metal bump 22 that is formed has a top surface that has curvature as illustrated in FIG. 4C. That is, each metal bump 22 has a curved top surface 22S. From a top down view, each metal bump 22 is substantially circular in shape. The curved top surface 22S of each metal bumps 22 extends to the outermost sidewall of the metal bumps 22 as shown in FIG. 4C. In the present application and due to the curvature of the top surface of each metal bump 22, a middle portion of each metal bump 22 has a height that is greater than a height of the outermost sidewall of the metal bump 22. In some embodiments, each metal bump 22 can have a substantially constant height (as measured from the middle portion of each metal bump 22). In other embodiments, a first set of metal bumps 22 can have a first height (as measured from the middle portion of each metal bump 22) and a second set of metal bumps 22 can have a second height (as measured from the middle portion of each metal bump 22) that differs from the first height. Other sets of metal bumps can also be present that have a same or different height as either the first height and/or the second height.

Referring now to FIG. 4D, there is illustrated the structure shown in FIG. 4C after removing the second photoresist layer 20 of the patterned bilayer photoresist. The second photoresist layer 20 of the patterned bilayer photoresist can be removed utilizing a material removal process that is selective in removing the second photoresist layer 20 relative to the first photoresist layer 18. The removal of the second photoresist layer 20 physically exposes the first photoresist layer 18 as shown in FIG. 4D.

Referring now to FIG. 4E, there is illustrated the structure shown in FIG. 4D during an initial stage of forming a first metal liner 26 in which a plating solution 25 is provided and thereafter a plate fixture 24 is brought into contact with, or close proximity to, each of the metal bumps 22. In the present application, the term “close proximity to” denotes that the plate fixture 24 is positioned up to 30 microns away from a topmost surface of each of the metal bumps 22. Typically, the plate fixture 24 is positioned from 1 micron to 5 microns away from a topmost surface of each of the metal bumps 22. When the plate fixture 24 contacts the metal bumps 22 it does so at a middle of the metal bumps 22 since the height of the middle of the metal bumps 22 is greater than other portions of the metal bumps 22.

In the present application, the structure shown in FIG. 4D is immersed in plating solution 25 which is designed for subsequent plating of the first metal liner 26; the structure shown in FIG. 4D can be rotated 90° before immersing it in the plating solution 25. A typical Cu plating solution can include, for example, copper sulfate, sulfuric acid, chloride ions, and organic additives. The plating solution 25 is present in a plating solution chamber (i.e., vessel) of any conventional plating apparatus which has been modified to include plate fixture 24 which can be moved in a horizontal direction, a vertical direction or both a vertical direction and a horizontal direction. With the structure shown in FIG. 4D immersed in plating solution 25, the plate fixture 24 is moved so as to be contact with, or close proximity to, each of the metal bumps 22.

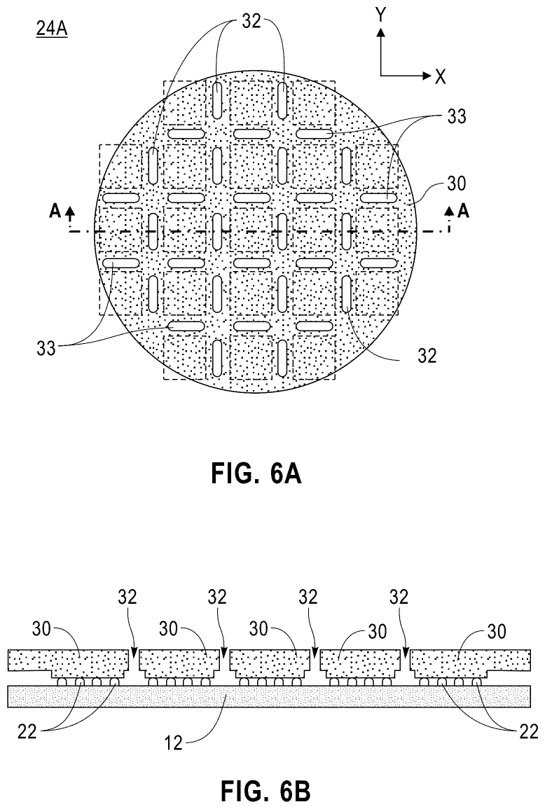

In the embodiment illustrated, plate fixture 24 is a solid piece having a flat contact surface. The plate fixture 24 can be composed of a glass or a semiconductor material. Although plate fixture 24 is shown as a solid piece, the present application contemplates using other types of plate fixtures such as will be described in greater detail herein below with respect to FIGS. 6A, 7A, 7B and 7C, and 8.

Referring now to FIG. 4F, there illustrated the structure shown in FIG. 4E during a step of refreshing the plating solution 25 in which the plate fixture 24 is removed from being in contact with, or close proximity to, each of the metal bumps 22. This allows fresh plating solution to by located between the plate fixture 24 and the metal bumps 22. The refreshing of the plating solution 25 is optional and not be employed in all instances. The refreshing of the plating solution 25 ensures that consumed metal ions and additives are at a proper level within the plating solution 25. After refreshing the plating solution 25, the plate fixture 24 can be moved to be in contact with, or in close proximity to, each of the metal bumps 22.

Referring now to FIG. 4G, there is illustrated the structure shown in FIG. 4F after plating the first metal liner 26 on physically exposed surfaces of each metal bump 22; plating is performed in the presence of both the plating solution 25 and the plate fixture 24 being in contact with, or in close proximity to, the metal bumps 22. The first metal liner 26 can be formed on physically exposed surfaces of each metal bump 22 on the structure illustrated in FIG. 4E without performing the refreshing step illustrated in FIG. 4F. The first metal liner 26 is composed of a third metal. The third metal that provides the first metal liner 26 can be compositionally the same as, or compositionally different from, the second metal that provides the metal bumps 22. Illustrative examples of third metals include, but are not limited to, Cu, Ni, Sn, In, Pd, Pt, Au or Ag.

In embodiments in with the plate fixture 24 is in proximity to the metal bumps 22, the first metal liner 26 can be formed on the outermost sidewall and on an entirety of the top surface of each of the metal bumps 22. In such embodiments, the first metal liner 26 can be referred to as an encapsulating first metal liner. In embodiments in with the plate fixture 24 is in contact with the metal bumps 22, the first metal liner 26 can be formed on the outermost sidewall and partially on the top surface of each of the metal bumps 22. In such embodiments, the first metal liner 26 can be referred to as a partially encapsulating first metal liner. In the case of the partially encapsulating first metal liner, the partially encapsulating first metal liner does not form at the apex of the curved top surface 22S (see, for example, the partially encapsulating first metal liner shown in FIG. 1B).

Collectively, each metal bump 22-first metal liner 26 combination provides a metal bump containing structure with a substantially flat top surface and enhanced coplanarity as compared to the metal bumps 22 by themselves, metal bumps with a dielectric or organic coating, or to CMP metal bumps. The metal bump containing structure having the flat surface and enhanced coplanarity, which achieves good joints with lower bonding force due to increased contact area, can reduce damage risks of a fragile low-k dielectric material in a BEOL and the metal bump 22 itself.

Referring now to FIG. 4H, there is illustrated the structure shown in FIG. 4G after removing the plate fixture 24 and plating a second metal liner 28 on the first metal liner 26. The removing the plate fixture 24 includes moving the plate fixture 24 from being in contact with, or close proximity to, each of metal bump containing structures. The plating of the second metal liner 28 can include using a new plating solution to deposit the second metal liner 28, or the same plating solution as used in forming the first material liner 26 can be used to deposit the second metal liner 28. The second metal liner 28 is composed of a fourth metal which can be compositional the same as, or compositionally different from, the third metal. Illustrative examples of the fourth metals that can be used in providing the second metal liner 28 include, but are not limited to, Ni, Au, Pd, Sn, In, Pd, Au or Ag. In some embodiments, the second metal liner 28 formation can be omitted. The presence of the second metal liner 28 can further improved the flatness and coplanarity of the metal liner containing metal bump structure and/or the second metal liner 28 can also be used to prevent surface oxidation or corrosion. Additional metal liners can be plating as desired.

Referring now to FIG. 4I, there is illustrated the structure shown in FIG. 4G after removing the first photoresist layer 18 of the patterned bilayer photoresist and removing physically exposed portions of the metal seed layer 16 and the adhesion layer 14. The first photoresist layer 18 is removed utilizing a material removal process that is selective in removing the first photoresist layer 18. The removal of the first photoresist layer 18 of the patterned bilayer photoresist physically exposes portions of the metal seed layer 16 in which metal bump formation was not performed. The physically exposes portions of the metal seed layer 16 and the underlying adhesion layer 14 are then removed utilizing one or more material removal processes that is (are) selective for removing the metal seed layer 16 and the underlying adhesion layer 14.

Referring now to FIG. 4J, there is illustrated an exemplary structure in which the electroplating process flow as illustrated in FIGS. 4A-4I has been modified such that second metal liner 28 is not formed.

Referring now to FIGS. 5A-5D, there are illustrated another process flow (i.e., electroless plating process flow) that can be employed in the present application in providing an exemplary structure in accordance with the present application. Electroless plating or electroless deposition (ED) is an autocatalytic process through which metals and metal alloys are deposited onto conductive surfaces.

Notably, the electroless plating process flow begins by providing the initial structure illustrated in FIG. 5A. The initial structure illustrated in FIG. 5A includes substrate 12 and metal bumps 22. Although the present application describes and illustrates a plurality of metal bumps 22, the present application can work when a single metal bump is formed. Each metal bump 22 is formed on metal seed layer 16. An optional adhesion layer 14 can be located between the substrate 12 and the metal seed layer 16., or the metal In the illustrated embodiment shown in FIG. 5A, the adhesion layer 14 (if present) is deposited on the substrate 12, and then the metal seed layer 16 is deposited on the adhesion layer 14 (if present) or directly on the substrate 12 if the adhesion layer 14 is not present. The as-deposited metal seed layer 16 and the as-deposited adhesion layer 14 are then patterned by lithography and etching, and thereafter metal bumps 22 are formed by electroless plating only on each metal seed layer 16 that remains after the patterning process. In some embodiments, the metal bumps 22 illustrated in FIG. 5A can be formed by a standard electroplating process, i.e., photoresist patterning, electroplating, photoresist removal and seed/adhesion layer etching instead of electroless plating.

Each metal bump 22 that is formed has a top surface that has curvature as illustrated in FIG. 5A That is, each metal bump 22 has a curved top surface. From a top down view, each metal bump 22 is substantially circular in shape. The curved top surface of each metal bumps 22 extends to the outermost sidewall of the metal bumps 22 as shown in FIG. 5A. In the present application, a middle portion of each metal bump 22 has a height that is greater than a height of the outermost sidewall of the metal bump 22. In some embodiments, each metal bump 22 can have a substantially constant height (as measured from the middle portion of each metal bump 22). In other embodiments, a first set of metal bumps 22 can have a first height (as measured from the middle portion of each metal bump 22) and a second set of metal bumps 22 can have a second height (as measured from the middle portion of each metal bump 22) that differs from the first height. Other sets of metal bumps can also be present that have a same or different height as either the first height and/or the second height.

Referring now to FIG. 5B, there is illustrated the structure shown in FIG. 5A during an initial stage of forming first metal liner 26 in which a plating solution 25 is provided and thereafter plate fixture 24 is brought into contact with, or close proximity to, each of the metal bumps 22. The plating solution 25 for this embodiment is an electroless plating solution. The plate fixture 24 for this embodiment is the same as that described above in respect to FIG. 4E, thus the description with respect to FIG. 4E applies here for FIG. 5B. Although plate fixture 24 is shown as a solid piece, the present application contemplates using other types of plate fixtures such as will be described in greater detail herein below with respect to FIGS. 6A, 7A, 7B and 7C, and 8.

Referring now to FIG. 5C, there is illustrated the structure shown in FIG. 5B during a step of refreshing the plating solution 25 in which the plate fixture 24 is removed from being contact with, or close proximity to, each of the metal bumps 22 to allow fresh plating solution to contact each of the metal bumps 22; the plate fixture 24 is then pushed back so as to be in contact with, or close proximity to, each of the metal bumps 22. The refreshing step illustrated in FIG. 5C is the same as the refresh step mentioned above in respect to FIG. 4F thus the description with respect to FIG. 4F applies here for FIG. 5C. Refreshing is optional and need not always be performed.

Referring now to FIG. 5D, there is illustrated the structure shown in FIG. 5C after plating first metal liner 26 on physically exposed surfaces of each metal bump 22. The first metal liner 26 can be formed on physically exposed surfaces of each metal bump 22 on the structure illustrated in FIG. 5B without performing the refreshing step illustrated in FIG. 5C. The first metal liner 26 used in providing the structure shown in FIG. 5D is the same as the first metal liner 26 used in forming the structure shown in FIG. 4G above, thus the description of the first metal liner 26 with respect to FIG. 4G applies here for the first metal liner 26 shown in FIG. 5D.

In embodiments in with the plate fixture 24 is in proximity to the metal bumps 22, the first metal liner 26 can be formed on the outermost sidewall and on an entirety of the top surface of each of the metal bumps 22. In such embodiments, the first metal liner 26 can be referred to as an encapsulating first metal liner. In embodiments in with the plate fixture 24 is in contact with the metal bumps 22, the first metal liner 26 can be formed on the outermost sidewall and partially on the top surface of each of the metal bumps 22. In such embodiments, the first metal liner 26 can be referred to as a partially encapsulating first metal liner. In the case of the partially encapsulating first metal liner, the partially encapsulating first metal liner does not form at the apex of the curved top surface (see, for example, partially encapsulating first metal liner 26P shown in FIG. 1B).

Collectively, each metal bump 22-first metal liner 26 combination provides a metal bump-containing structure with a substantially flat top surface and enhanced coplanarity as compared to the metal bumps 22 by themselves or to CMP metal bumps. The metal bump containing structure having the flat surface and enhanced coplanarity, which achieves good joints with lower bonding force due to increased contact area, can reduce damage risks of fragile a low-k dielectric material in the BEOL and the metal bump 22 itself

Referring now to FIG. 5E, there is illustrated the structure shown in FIG. 5D after removing the plate fixture 24 and plating second metal liner 28 on the first metal liner 26. The removing the plate fixture 24 includes moving the plate fixture 24 from being in contact with, or close proximity to, each of metal liner containing metal bump structures. The plating of the second metal liner 28 can include using a new plating solution to deposit the second metal liner 28, or the same plating solution as used in forming the first material liner 26 can be used to deposit the second metal liner 28. The second metal liner 28 is composed of a fourth metal as previously described hereinabove. Additional metal liners can be formed as desired. In some embodiments, the second metal liner 28 formation can be omitted. The presence of the second metal liner 28 can further improved the flatness and coplanarity of the metal liner containing metal bump structure, and/or the second metal liner 28 can also be used to prevent surface oxidation or corrosion.

Referring now to FIG. 6A, there is illustrated a plate fixture 24A that can be employed in accordance with an embodiment of the present application. The plate fixture 24A illustrated in FIG. 6A can be used instead of the plate fixture 24 mentioned above for the an electroplating process flow illustrated in FIGS. 4A-4J or the electroless process flow illustrated in FIGS. 5A-5E. The plate fixture 24A illustrated in FIG. 6A includes a base sheet 30 that has a first array of holes 32 oriented in a first direction (i.e., the y-direction illustrated in FIG. 6A), and a second array of holes 33 oriented in a second direction which is perpendicular to the first direction (i.e., the x-direction illustrated in FIG. 6A). Although the present application describes and illustrates a first array of holes 32 and a second array of holes 33, it is possible to omit either the first array of holes 32 or the second array of holes 33 from the plate fixture 24A. In this embodiment, each of the holes is a through-hole that extends entirely through the base sheet 30. In embodiments, the holes in the base sheet 30 can be randomly oriented. The base sheet 30 can be composed of a semiconductor material or glass, and first array of holes 32 and the second array of holes 33 can be formed utilizing techniques well known in the art. For example, the first and second array of holes can be formed by photolithography and etching. The first array of holes 32 and the second array of holes 33 provide better flow of plating solution, and better current density in the case of electroplating. In FIG. 6A, the dotted boxes designate areas raised of the plate fixture 24A that can come into contact with the metal bumps 22.

Referring now to FIG. 6B, there is illustrated the application of the plate fixture 24A shown in FIG. 6A during an initial stage of plating the first metal liner 26 on metal bumps 22 that are formed on substrate 12. In FIG. 6B, the plating solution 25, the optional adhesion layer 14 and the metal seed layer 16 are not shown but would nevertheless be present.

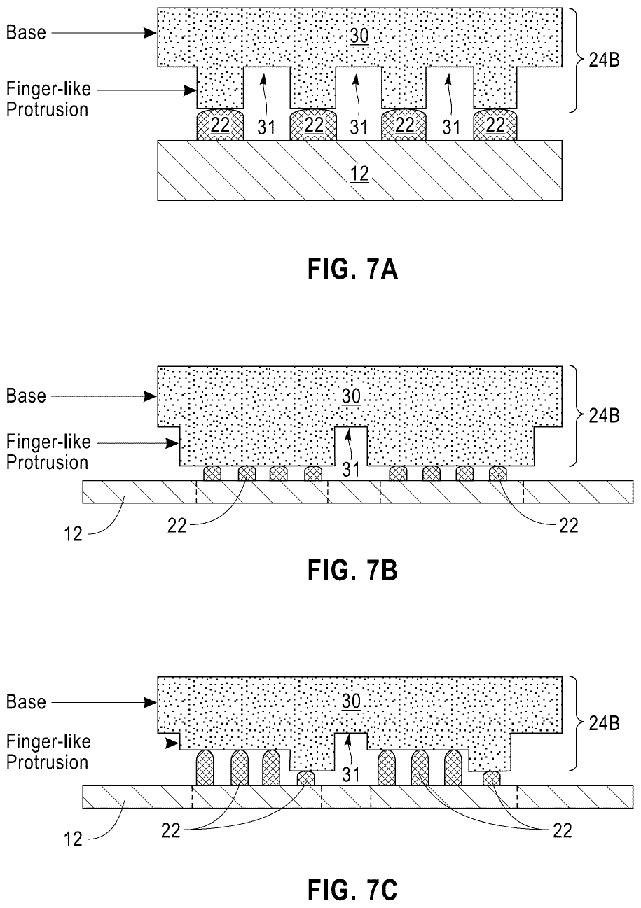

Referring now to FIGS. 7A, 7B and 7C, there are illustrated plate fixtures 24B including at least one cavity 31 that can be employed in accordance with various embodiments of the present application. Also, shown in each of FIGS. 7A, 7B and 7C is substrate 12 and metal bumps 22. In FIGS. 7A, 7B and 7C, the plating solution 25, the optional adhesion layer 14 and the metal seed layer 16 are not shown but would nevertheless be present. The plate fixtures 24B illustrated in FIGS. 7A, 7B and 7C can be used instead of the plate fixture 24 mentioned above for the an electroplating process flow illustrated in FIGS. 4A-4J or the electroless process flow illustrated in FIGS. 5A-5E. Notably, each of the plate fixtures 24B includes base sheet 30 that has been processed to include finger-like protrusions that extend outward from a base. The finger-like protrusions are used as a contact surface for at least some of the metal bumps 22. Different height finger-like protrusions can be designed as shown in FIG. 7C to be used in cases when the metal bumps 22 have a height variation. Unlike the holes shown in FIG. 6A, the cavities 31 shown in FIGS. 7A, 7B and 7C do not extend entirely through the base sheet 30. Each cavity 31 is defined as an area between two adjacent finger-like protrusions. The plate fixtures 24B illustrated in FIGS. 7A, 7B and 7C provide more plating chemical near each of the metal bumps 22 and enhanced flow of plating solution to those metal bumps 22.

Referring now to FIG. 8, there is illustrated a plate fixture 24C including slits 34 and a sealing edge 36 that can be employed in accordance with an embodiment of the present application. The plate fixture 24C illustrated in FIG. 8 can be used instead of the plate fixture 24 mentioned above for the an electroplating process flow illustrated in FIGS. 4A-4J or the electroless process flow illustrated in FIGS. 5A-5E. The plate fixture 24C includes base sheet 30 which was been processed to include slits 34. The slits 34 extend entirely through the base sheet 30. Some of the slits 34 can be used as plating solution outlets, while other slits 34 can be used for plating solution inlets. The inlet and outlets can be used for jet agitation. The sealing edge 36 is composed of a sealing material such as, for example, a rubber casket. The sealing edge 36 can extend entirely around the circumference of the plate fixture 24C or can be partially formed around the circumference of the plate fixture 24C, as is the case shown in FIG. 8. The presence of the inlets providing by some of the slits 34 in the plate fixture 24C provides a means to maintain a substantially constant concentration of plating chemical near each of the metal bumps 22 during the plating of the first metal liner 26. The sealing edge 36 can be used to provide a control flow of plating solution to each of the metal bumps 22.

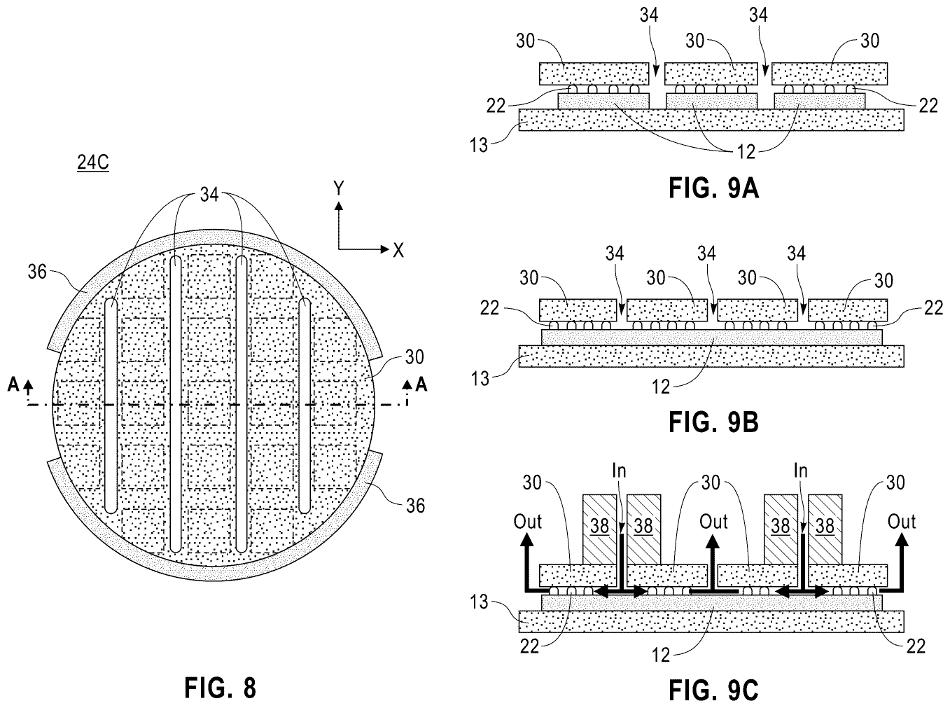

Referring now to FIG. 9A, there is illustrated plate fixture 24C as shown in FIG. 8 for application with a plurality of substrates 12 containing metal bumps 22. In this exemplary embodiment each of the of substrates 12 can be a die (or chip) or a chiplet. Each substrate 12 can be attached to a carrier substrate 13. In FIG. 9A, the plating solution 25, the optional adhesion layer 14 and the metal seed layer 16 are not shown but would nevertheless be present.

Referring now to FIG. 9B, there is illustrated a plate fixture as shown in FIG. 8 for application with a single substrate 12 containing metal bumps 22. In this exemplary embodiment the substrate 12 can be a wafer, die (or chip) or a chiplet. Each substrate 12 can be attached to a carrier substrate 13. In FIG. 9B, the plating solution 25, the optional adhesion layer 14 and the metal seed layer 16 are not shown but would nevertheless be present.

Referring now to FIG. 9C, there is illustrated plate fixture 24C as shown in FIG. 8 for application with a substrate 12 containing metal bumps 22 illustrating inlet slits and outlet slits. In this exemplary embodiment, the substrate 12 can be a wafer, die (or chip) or a chiplet. In FIG. 9C, the plating solution 25, the optional adhesion layer 14 and the metal seed layer 16 are not shown but would nevertheless be present.

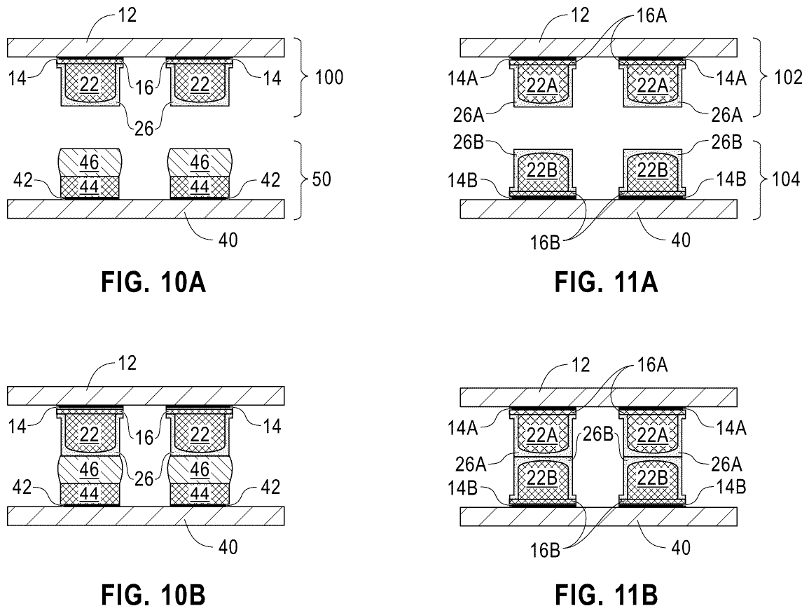

Referring now to FIGS. 10A and 10B, there are illustrated a bonding process in accordance with an embodiment of the present application. The bonding process illustrated in FIGS. 10A-10B joins a metal bump containing structure in accordance with the present application to solder. Notably, FIG. 10A illustrates an initial stage of the bonding process in accordance with an embodiment of the present application. As is illustrated in FIG. 10A, a first structure 100 is provided that includes substrate 12, adhesion layer 14 (this layer is optional), metal seed layer 16, and a pair of metal bump containing structures in accordance with the present application. Each metal bump containing structure includes metal bump 22 and first metal liner 26 (in this illustrated embodiment, the first metal liner 26 fully encapsulates the metal bump 22). It is noted that while the first structure 100 shown in FIG. 10A includes a pair of metal bump containing structures, the exemplified bonding process is not limited to such a number of metal bump containing structures. The metal bump containing structures present in the first structure 100 are equivalent to the metal bump containing structures shown in the first exemplary structure 100A illustrated in FIG. 1A. While the metal bump containing structures shown in FIG. 1A are used in the exemplary bonding process, other metal bump containing structures including those illustrated in the second, third and fourth exemplary structures (100B, 100C, and 100D) of the present application can be used.

A second structure 50 is also illustrated in FIG. 10A which includes substrate 40, an optional second substrate adhesion layer 42, under bump metallurgy (UBM) 44 and solder 46. The substrate 40 can include materials mentioned above for substrate 12. The substrate 40 can be a wafer, die (or chip), chiplet, or panel. The optional second substrate adhesion layer 42 can include materials mentioned above for adhesion layer 14. The UBM can include one or more UBM metals such as, for example, Cu, Ni, or NiP/Pd/Au. The solder 46 can include lead-free solder, or lead containing solder. The second structure 50 can be formed utilizing techniques well known in the art.

In the initial stage, one of the first structure 100 or the second structure 50 is aligned over the other structure. In FIG. 10A, the first structure 100 is aligned above the second structure 50 such that each metal bump containing structures of the first structure 100 is aligned above solder 46 of the second structure 50.

Referring now to FIG. 10B, there is illustrated a final stage of the bonding process in accordance with an embodiment of the present application. The final stage of the bonding process includes bringing the first structure 100 and the second structure 50 into intimate contact with each other; notably, each metal bump containing structure is brought into intimate contact with solder 46 of the second structure 50. The bonding process continues by heating the contacted first and second structures to facilitate bonding between each metal bump containing structure and solder 46. The heating that facilitates bonding can be performed at a temperature below, or above melting point of solder 46. In one example, the heating can be performed at about nominal room temperature (i.e., above 20° C.) to about 400° C. In cases in which heating is performed below the metal point of solder 46, the bond is achieved by solid-solid diffusion, whereas in cases in which is heating is performed above the melting temperature of solder 46, the bond is achieved by solid-liquid diffusion. The heating causes the formation of a bond between each metal bump containing structure and solder 46 and thus the first structure 100 is now electrically connected to the second structure 50.

Referring now to FIGS. 11A and 11B, there are illustrated another bonding process in accordance with an embodiment of the present application. The bonding process illustrated in FIGS. 11A-11B joins a metal bump containing structure in accordance with the present application to another metal bump containing structure in accordance with the present application. As is illustrated in FIG. 10A, a first structure 102 is provided that includes a substrate 12, adhesion layer 14A (this layer is optional), metal seed layer 16A, and a first pair of metal bump containing structures in accordance with the present application. Each metal bump containing structure of the first pair of metal containing structures includes metal bump 22A and first metal liner 26A (in this illustrated embodiment, the first metal liner 26A fully encapsulates the metal bump 22A). It is noted that while the first structure 102 shown in FIG. 11A includes a pair of first metal bump containing structures, the exemplified bonding process is not limited to such a number of metal bump containing structures. The metal bump containing structures present in the first structure 102 are equivalent to the metal bump containing structures shown in FIG. 1A. While the metal bump containing structures shown in FIG. 1A are used in the exemplary bonding process, other metal bump containing structures of the present application can be used.

A second structure 104 is also illustrated in FIG. 11A which includes substrate 40, adhesion layer 14B (this layer is optional), metal seed layer 16B, and a second pair of metal bump containing structures in accordance with the present application. Each metal bump containing structure of the second pair of metal containing structures includes metal bump 22B and first metal liner 26B (in this illustrated embodiment, the first metal liner 26B fully encapsulates the metal bump 22B). It is noted that while the second structure 104 shown in FIG. 11B includes a pair of second metal bump containing structures, the exemplified bonding process is not limited to such a number of metal bump containing structures. The metal bump containing structures present in the second structure 104 are equivalent to the metal bump containing structures shown in FIG. 1A. While the metal bump containing structures shown in FIG. 1A are used in the exemplary bonding process, other metal bump containing structures of the present application can be used.

In the initial stage, one of the first structure 102 or the second structure 104 is aligned over the other structure. In FIG. 11A, the first structure 102 is aligned above the second structure 104 such that each metal bump containing structures of the first structure 102 is aligned above a metal bump containing structure of the second structure 104.

Referring now to FIG. 11B, there is illustrated a final stage of the bonding process in accordance with an embodiment of the present application. The final stage of the bonding process includes bringing the first structure 102 and the second structure 104 into intimate contact with each other; notably, each metal bump containing structure is brought into intimate contact with one of metal bump containing structures of the second structure 104. The bonding process continues by heating the contacted first and second structure to facilitate bonding between each metal bump containing structure of the first structure 102 and each metal bump containing structure of the second structure 104. The heating that facilitates bonding can be performed at a temperature below, or above melting point of the solder that is employed. In one example, the heating can be performed at about nominal room temperature (i.e., above 20° C.) to about 400° C. In cases in which heating is performed below the metal point of the solder, the bond is achieved by solid-solid diffusion, whereas in cases in which is heating is performed above the melting temperature of the solder, the bond is achieved by solid-liquid diffusion. The heating causes the formation of a bond between each metal bump containing structure of the first structure 102 and each metal bump containing structure of the second structure 104 and thus the first structure 102 is now electrically connected to the second structure 104.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A structure comprising:
a metal bump containing structure having a substantially flat top surface and located on top of a substrate, the metal bump containing structure comprises a metal bump having a curved top surface, and a first metal liner located along an outermost sidewall and present at least partially on the curved top surface of the metal bump.

2. The structure of claim 1, wherein the metal bump is disposed on a metal seed layer, and the metal seed layer is composed of a first metal and the metal bump is composed of a second metal.

3. The structure of claim 2, wherein the first metal is compositionally a same metal as the second metal.

4. The structure of claim 2, wherein the first metal is compositionally different from the second metal.

5. The structure of claim 2, wherein the metal seed layer has a width that is larger than a width of the metal bump.

6. The structure of claim 2, wherein the metal seed layer has a same width as the metal bump.

7. The structure of claim 1, further comprising an adhesion layer located between the metal bump containing structure and the substrate.

8. The structure of claim 1, wherein the metal bump is composed of a second metal and the first metal liner is composed of a third metal, and the second metal is compositionally the same as the third metal.

9. The structure of claim 1, wherein the metal bump is composed of a second metal and the first metal liner is composed of a third metal, and the second metal is compositionally different than the third metal.

10. The structure of claim 1, further comprising a second metal liner located on the first metal liner.

11. The structure of claim 1, wherein the first metal liner is present entirely along the curved top surface of the metal bump.

12. The structure of claim 1, wherein the first metal liner is present partially along the curved top surface of the metal bump.

13. The structure of claim 1, further comprising at least one other metal bump containing structure having a substantially flat top surface and located on top of the substrate, the at least one other metal bump containing structure comprises another metal bump having a curved top surface, and another first metal liner located along an outermost sidewall and present at least partially on the curved top surface of the least one other metal bump containing structure, wherein the at least one other metal bump containing structure is spaced apart from the metal bump containing structure, and the substantially flat top surface of the at least one other metal bump containing structure is coplanar with the substantially flat top surface of the metal bump containing structure.

14. The structure of claim 1, wherein the metal bump containing structure is joined to solder, or to another metal bump containing structure.

15. A method comprising:
forming a metal seed layer on a substrate;
plating a metal bump on the metal seed layer, the metal bump having a curved top surface; and
plating a first metal liner on an outermost sidewall and at least partially on the curved top surface of the metal bump, wherein the plating of the first metal liner is performed in a plating solution and in the presence of a plate fixture that is in contact with, or close proximity to, the metal bump.

16. The method of claim 15, wherein the plate fixture is a solid piece having a flat contact surface.

17. The method of claim 15, wherein the plate fixture comprises a base sheet having a plurality of holes that extend entirely through the base sheet.

18. The method of claim 15, wherein the plate fixture comprises a base and finger-like protrusions extending from the base, wherein a cavity is located between each neighboring pair of finger-like protrusions.

19. The method of claim 15, wherein the plate fixture comprises a base sheet having silts that extending entirely through the base sheet, wherein a first set of the silts are configured as plating solution inlets and a second set of the silts are configured as plating solution outlets.

20. The method of claim 15, wherein the plating of the metal bumps composes electroplating or electroless plating.
